(19) United States
(12) Patent Application Publication
(10) Pub. No.: US 2026/0081098 A1
(43) Pub. Date: Mar. 19, 2026

(54) CHARGED PARTICLE BEAM DEVICE AND METHOD FOR CORRECTING ASTIGMATISM AND NUMERICAL APERTURE

(71) Applicant: ICT Integrated Circuit Testing Gesellschaft für Halbleiterprüftechnik mbH, Heimstetten (DE)

(72) Inventors: Dominik Patrick Ehberger, Ebersberg (DE); John Breuer, München (DE); Thomas Kemen, Meppen (DE)

(73) Assignee: ICT Integrated Circuit Testing Gesellschaft für Halbleiterprüftechnik mbH, Heimstetten (DE)

(21) Appl. No.: 18/889,761

(22) Filed: Sep. 19, 2024

(51) Int. Cl. H01J 37/153; H01J 37/304

(52) U.S. Cl. CPC H01J 37/153; H01J 37/304; H01J 2237/1532

(57) ABSTRACT

According to an embodiment, a method of correcting an astigmatism and adjusting a numerical aperture of a charged particle beam is described. The astigmatism is corrected and the numerical aperture is adjusted with a double stigmator. The double stigmator has a first stigmator and a second stigmator. The method comprises correcting the astigmatism of the charged particle beam with the second stigmator of a double stigmator; and adjusting the numerical aperture of the charged particle beam with the first stigmator of the double stigmator. The first stigmator and the second stigmator are spaced apart along an optical axis.

### TECHNICAL FIELD OF THE INVENTION

Embodiments of the invention relate to charged particle beam devices. Particularly embodiments relate a method of correcting an astigmatism and a numerical aperture of a charged particle beam, and a charged particle beam device comprising a double stigmator. Specifically, embodiments relate to a method of correcting an astigmatism and adjusting a numerical aperture of a charged particle beam, and a charged particle beam device.

### BACKGROUND OF THE INVENTION

Charged particle beams have many functions in a plurality of industrial fields, including, but not limited to, inspection of semiconductor devices during manufacturing, exposure systems for lithography, detecting devices and testing systems. Thus, there is a high demand for structuring and inspecting specimens within the micrometer and nanometer scale.

Micrometer and nanometer scale process control, inspection or structuring, is often done with charged particle beams, e.g., electron beams, which are generated and focused, in charged particle beam devices, such as electron microscopes or electron beam pattern generators. Charged particle beams offer superior spatial resolution compared to, e.g. photon beams due to their short wavelengths.

Particle beam optical systems suffer from various types of imperfections, e.g. mechanical manufacturing imperfections, misalignment of optical components, material inhomogeneities, imperfections of the electric and magnetic fields used for focusing, aligning and adjusting, electron optical aberrations, contaminations and charging of beam steering components. A good electron optical design aims at minimizing imperfections, and particularly to reduce aberrations. For example, aberrations can be corrected.

However, with these measures alone the theoretical optical performance will not be obtainable. Therefore, a lot of devices and methods have been devised over the years which allow counteracting the influence of the herein mentioned aberrations and imperfections. Such devices can be, amongst others, dipole deflectors (to correct misalignment between components), quadrupole stigmators (to correct axial astigmatism in the image), heated sample holders and apertures (to avoid contamination and/or subsequent charging), in-situ plasma cleaning (to remove contaminations in the beam line), and the like.

The aforementioned imperfections become more noticeable if resolution improves so that the spot deterioration becomes clearly visible, the beam leaves the paraxial region around the optical axis and experiences higher order aberrations, the beam current is increased, and/or the beam bundle diameter is increased, in order to reduce electron-electron interaction.

For electron beam imaging, for example, for defect review, critical dimensioning, inspection, etc., aberrations are beneficially corrected. However, correction, for example correction of astigmatism, results in further modifications to the charged particle beam. Accordingly, it is beneficial to correct, for example astigmatism, without influencing other characteristics of a charged particle beam.

### SUMMARY OF THE INVENTION

In light of the above, a method of correcting an astigmatism and adjusting a numerical aperture, and a charged particle beam device, as claimed are provided. Further advantages, features, aspects and details are evident from the dependent claims, the description and the drawings.

According to an embodiment, a method of correcting an astigmatism and adjusting a numerical aperture of a charged particle beam is provided. The astigmatism is corrected and the numerical aperture is adjusted with a double stigmator. The double stigmator has a first stigmator and a second stigmator. The method comprises correcting the astigmatism of the charged particle beam with the second stigmator of a double stigmator; and adjusting the numerical aperture of the charged particle beam with the first stigmator of the double stigmator. The first stigmator and the second stigmator are spaced apart along an optical axis.

According to an embodiment, a charged particle beam device is provided. The charged particle beam device includes a charged particle beam column, a charged particle beam source provided within the charged particle beam column and configured to emit a charged particle beam along an optical axis, an objective lens configured to focus the charged particle beam on a specimen, a stage configured to support the specimen, and a double stigmator configured to correct an astigmatism and a numerical aperture. The double stigmator includes a first stigmator, a second stigmator, the first stigmator and the second stigmator being separated along the optical axis, and a controller configured to perform any method described herein.

Embodiments are also directed at apparatuses for carrying out the disclosed methods and include apparatus parts for performing each described operation. These operations may be performed by way of hardware components, a computer programmed by appropriate software, by any combination of the two or in any other manner. Furthermore, embodiments according to the invention are also directed at methods by which the described apparatus operates. It includes operations for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIGS. 1A to 1D illustrate, schematically, charged particle beam devices with a double stigmator in two planes and being adapted for correcting an astigmatism and a numerical aperture of a charged particle beam according to embodiments described herein;

FIGS. 2A to 2B illustrate flow charts for illustrating embodiments of methods for correcting an astigmatism and a numerical aperture of a charged particle beam; and

FIGS. 3A and 3B illustrate graphs depicting a proof of concept of correcting an astigmatism and a numerical aperture.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that such exemplary modifications and variations are included.

Without limiting the scope of protection of the present application, in the following, the charged particle beam device or components thereof will exemplarily be referred to as a charged particle beam device including the correction of astigmatism and/or numerical aperture. Embodiments of the present invention can still be applied for apparatuses and components detecting corpuscles, such as secondary and/or backscattered charged particles in the form of electrons or ions, photons, X-rays or other signals in order to obtain a specimen image. Generally, when referring to corpuscles they are to be understood as light signals in which the corpuscles are photons as well as particles, in which the corpuscles are ions, atoms, electrons or other particles.

A “specimen” as referred to herein, includes, but is not limited to, semiconductor wafers, semiconductor workpieces, and other workpieces such as memory disks and the like. Embodiments of the invention may be applied to any workpiece on which material is deposited or which is structured. A specimen includes a surface to be structured or on which layers are deposited, an edge, and typically a bevel. According to some embodiments, which can be combined with other embodiments described herein, the apparatus and methods are configured for or are applied for Scanning Electron Microscopy (SEM), for critical dimensioning applications, defect review applications, etc. Accordingly, it is desirable to provide a device which corrects astigmatism and numerical aperture and a method of correcting astigmatism and numerical aperture of such a device. This improves the matching and the alignment of the charged particle beam. In better matching and aligning the charged particle beam, the precision is improved, which in turn can reduce the overall cycle time during inspection and/or defect detection operation. This degree of alignment increases the precision of performance and requires minimal external input, ultimately reducing the cost of operation.

Generally, when referring to focusing a charged particle beam, it is understood that the beam of charged particles is reduced in divergence. This means, the charged particles of a beam are focused or at least collimated towards a subsequent beam optical element to decrease losses of charged particles due to divergence or due to blocking of charged particles. Defocusing is understood as moving the focus position away from the sample plane. Further, it is understood that in the literature of the technical field, the term “octopole” and “octupole” are used similarly; herein reference is made to “octupole”, which can be replaced by “octopole” and vice versa.

Embodiments of the invention relate to a double stigmator compensation element for particle beam systems, for example, for electron microscopes SEM, e.g. for defect review or critical dimension measurement, for focused ion beam systems etc. These embodiments described herein are particularly, but not only, useful for the correction of electron beams with astigmatism and (potentially resulting) asymmetric numerical aperture. Other types of charged particle characteristics could also be corrected by the device.

Particularly for such described applications, a single quadrupole stigmator may not be sufficient to control the astigmatism and numerical aperture, and to obtain the best resolution. In order to compensate for two-fold astigmatism of a charged particle beam device, some embodiments include correcting and/or adjusting scheme which allows for correcting of an astigmatism and adjusting a numerical aperture through a double stigmator, wherein a first stigmator and a second stigmator are spaced apart along an optical axis.

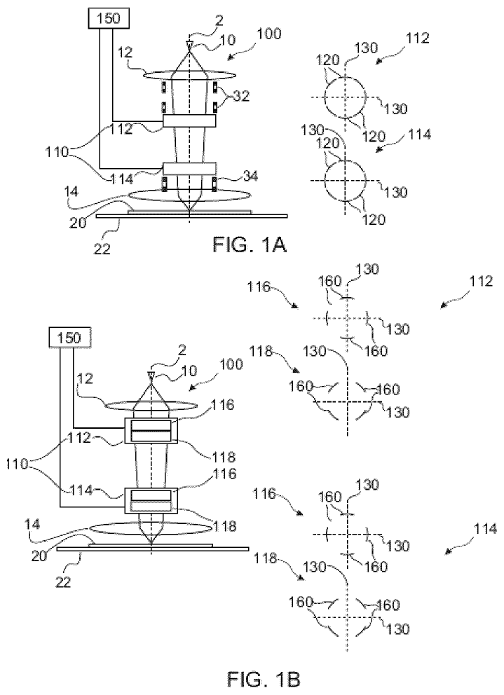

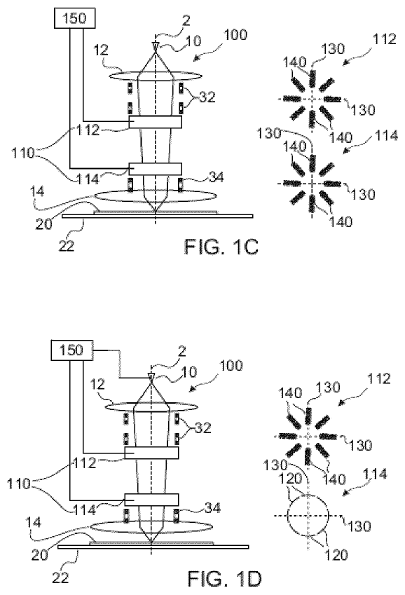

FIG. 1A shows a charged particle beam device 100. The charged particle beam device includes a charged particle beam column. The charged particle beam device further includes a charged particle beam source 10, for example an emitter, which is provided in the charged particle beam column. The charged particle beam source 10 is configured to emit a charged particle beam, for example an electron beam, along an optical axis 2. The charged particle beam source can have an emitter tip, which is focused on a specimen 20 with a lens assembly. The charged particle beam device further includes an objective lens 14, wherein the objective lens 14 is configured to focus the charged particle beam on a specimen 20. According to embodiments described herein, which can be combined with other embodiments described herein, the charged particle beam device can include a condenser lens 12 and the objective lens 14. According to typical modifications, the condenser lens 12 can also be replaced by a condenser lens assembly having one, two or three condenser lenses.

A lens assembly with rotational symmetric lenses can be utilized to focus the charged particle beam on the specimen 20. A stage 22 is configured to support the specimen 20, particularly during the operation of the charged particle beam device 100. The charged particle beam device 100 includes a double stigmator 110, wherein the double stigmator 110 is configured to correct an astigmatism and a numerical aperture. The double stigmator 110 includes a first stigmator 112 and a second stigmator 114, the first stigmator 112 and the second stigmator 114 being separated along the optical axis 2. The charged particle beam device 100 further includes a controller 150, wherein the controller 150 is configured to perform the method according to any of the embodiments described herein. The controller 150 can be connected to the first stigmator 112 and the second stigmator 114.

According to some embodiments, as shown in FIG. 1A, alignment deflectors 32 can be provided in the charged particle beam device 100. It can be understood that even though the alignment deflectors 32, which are exemplarily shown as double stage alignment deflection system in FIG. 1A, are shown in one direction, alignment deflectors 32 can also be provided in a second direction, for example, perpendicular to the paper plane in FIG. 1A.

According to embodiments described herein, which can be combined with other embodiments, a scanning deflector 34 can be provided for scanning the charged particle beam over the specimen 20 as illustrated in FIG. 1A. According to typical modifications of herein-described embodiments, alignment deflectors 32 and/or scanning deflectors 34 can be magnetic (as shown in FIG. 1A), electric or combined electric-magnetic.

The charged particle beam device 100 includes the double stigmator 110, which includes the first stigmator 112 and the second stigmator 114, for correcting the astigmatism and the numerical aperture of the charged particle beam. The double stigmator 110 can include a plurality of poles. Preferably, the double stigmator 110 can include 12 or more poles, particularly 16 or more poles. The double stigmator can include magnetic poles, electric poles, or a combination of magnetic poles and electric poles. For example, the double stigmator 110 can include any of 16 or more magnetic poles, 16 or more electric poles, or a combination of 16 or more poles including magnetic poles and electric poles. According to some embodiments, which can be combined with other embodiments described herein, each stigmator of the double stigmator can include 6 or more poles to correct the astigmatism in 2 directions. Beneficially, 8 or more poles may be used for each stigmator of the double stigmator.

According to typical embodiments, the double stigmator 110 is adapted for compensating a two-fold astigmatism and can have at least a twelve-pole, particularly a sixteen-pole compensation capability. A three-fold astigmatism can be corrected with a hexapole field, for example with a hexapole-stigmator. A four-fold astigmatism can be corrected in one direction with an octupole field.

Within the context of the present disclosure a charged particle beam device with correction of astigmatism and correction of numerical aperture is provided. Astigmatism is commonly referred to as aberrations. Systems including aberration correction can include fields with rotational symmetry, such as dipoles, hexapoles, quadrupoles, and octupoles. The beam may have astigmatism and has a numerical aperture. The beam can have a symmetrical numerical aperture or an asymmetrical numerical aperture.

A correction of the astigmatism and a numerical aperture utilizes higher order multipoles, for example a double stigmator comprising 16 poles. Inaccuracies can be for example, misalignment of optical components, material inhomogeneities, imperfections of the electric and/or magnetic fields used for focusing, aligning and adjusting, contaminations and charging of beam steering components, etc. These inaccuracies result in loss of continuous rotational symmetry (continuous rotation symmetry vs. discrete rotational symmetry being n-fold), resulting in, for example, asymmetrical inaccuracies such as astigmatism and asymmetric numerical aperture. Accordingly, lenses and fields are typically referred to as essentially symmetric within the present disclosure. The resulting field distortions can be described by a multipole expansion, and the multipole components can be beneficially corrected as described herein.

For example, a deflection of the beam can be corrected with a dipole, for example, the alignment deflector 32 as shown in FIG. 1, and as known in the art. An axial astigmatism in one direction can be corrected with a quadrupole, for example a stigmator. Astigmatism in all directions can be corrected with a hexapole, particularly an octupole or two quadrupoles. According to embodiments described herein, which can be combined with other embodiments described herein, a numerical aperture can be corrected with a first stigmator 112 of the double stigmator 110 of the charged particle beam device 100, and a two-fold astigmatism can be corrected with a second stigmator 114 of the double stigmator 110 of the charged particle beam device 100. Particularly, in the event of a symmetric numerical aperture, the first stigmator 112 can correct an asymmetry of the numerical aperture that has been introduced by the second stigmator 114. In the event of an asymmetric numerical aperture, the second stigmator can correct an asymmetry of the numerical aperture introduced by the first stigmator and the initial asymmetry of the numerical aperture.

Scanning Electron Microscopy systems, for example, SEM systems utilize according to embodiments described herein, a numerical aperture in a range of 1 to 30 mrad for typical SEMs and up to 100 mrad for aberration-corrected SEMs. Further, beam currents in a range of 10 pA to 300 nA can be provided.

The first stigmator 112 and the second stigmator 114 of the double stigmator 110 are separated along the optical axis 2. The first stigmator 112 can be positioned closer to the condenser lens 12, and the second stigmator 114 can be positioned closer to the objective lens 14. The larger a distance between the first stigmator 112 and the second stigmator 114, the better, because for example, the first stigmator 112 can make a more purposeful correction to the numerical aperture and the second stigmator 114 can make a more purposeful correction to the astigmatism. Providing a larger distance between the first stigmator 112 and the second stigmator 114 can also provide the benefit of allowing the corrections to the astigmatism to be more relevant, in comparison with having the first stigmator 112 and the second stigmator 114 closer together, e.g. nearly in an identical plane.

According to some embodiments, which can be combined with other embodiments described herein, the stigmator closer to objective lens has more impact on astigmatism and the one further away (close to the condenser lens) has more impact on the NA.

For example, the first stigmator 112 and the second stigmator are separated by at least 30 mm. In some embodiments, the first stigmator 112 and the second stigmator 114 are separated by at least 50 mm along the optical axis, preferably by at least 70 mm along the optical axis. For example, in some embodiments, the first stigmator 112 and the second stigmator 114 are separated by 100 mm or more.

According to some embodiments, each stigmator, for example the first stigmator 112 and the second stigmator 114 of the double stigmator 110, is fixed in its position along the optical axis. According to some embodiments, each stigmator, for example the first stigmator 112 and the second stigmator 114 of the double stigmator 110, is fixed in its position with respect to a rotation around the optical axis. Each stigmator, for example the first stigmator 112 and the second stigmator 114 of the double stigmator 110, can be fixed in its position during the operation of the charged particle beam device 100. Each stigmator, for example the first stigmator 112 and the second stigmator 114 of the double stigmator 110, can be fixed in its position prior to and/or after the operation of the charged particle beam device 100. Accordingly, in some embodiments, the first stigmator 112 and the second stigmator 114 can be fixed relative to one another. The first stigmator 112 and the second stigmator 114 can be fixed relative to one another with respect to the distance, for between the distance between the first stigmator 112 and the second stigmator 114 along the optical axis. The first stigmator 112 and the second stigmator 114 can be fixed relative to one another with respect to the rotation angle. The first stigmator 112 can have the same rotation angle as the second stigmator 114. For example, if the first stigmator 112 has a rotation angle of 0° and the second stigmator 114 has a rotation angle of 0°. According to some embodiments, the first stigmator and the second stigmator have the same rotation, e.g. upon a projection onto the stage or a specimen, the orientation and/or the arrangement of poles of the first stigmator and the second stigmator cannot be distinguished.

According to some embodiments, the first stigmator 112 and the second stigmator 114 are configured to independently control four degrees of freedom. The four degrees of freedom are numerical aperture in an X-axis and numerical aperture in a Y-axis, and astigmatism in an X-axis and astigmatism in a Y-axis. Independently controlling four degrees of freedom allows for a better and more accurate control mechanism and methodology, because if one or more of the degrees of freedom is sufficient, the remaining degree or degrees of freedom can be independently controlled to meet sufficiency requirements, resulting in for example, having a minimal to zero effect on the sufficient degree or degrees of freedom.

According to some embodiments, the first stigmator 112 and the second stigmator 114 have the same rotation orientation. In FIG. 1A, axes 130 of the first stigmator 112 and axes 130 of the second stigmator 114 are essentially the same, and in particular are the same.

According to some embodiments, the double stigmator 110 is configured to adjust asymmetric numerical aperture. Adjusting of the asymmetric numerical aperture can comprise correcting the asymmetric numerical aperture.

According to some embodiments, each stigmator, for example the first stigmator 112 and the second stigmator 114 of the double stigmator 110, can include an octupole (120, 140). Each octupole can be provided by two quadrupoles, in particular, wherein the two quadrupoles are in the same plane along the optical axis 2. According to some embodiments the two quadrupole can be in the same plane. According to some embodiments the two quadrupole can be close to each other, e.g. within a distance along the optical axis of 20 mm or below.

Each octupole (120, 140) can be an electric octupole (120) or a magnetic octupole (140). The double stigmator 110 can include the first stigmator 112 including an electric octupole and the second stigmator 114 including an electric octupole. The double stigmator 110 can include the first stigmator 112 including a magnetic octupole and the second stigmator 114 including a magnetic octupole. The double stigmator 110 can include the first stigmator 112 including an electric octupole and the second stigmator 114 including a magnetic octupole or the first stigmator 112 including a magnetic octupole and the second stigmator 114 including an electric octupole. According to some embodiments, which can be combined with other embodiments described herein, each stigmator can include combined magnetic and electrostatic multipoles, e.g. quadrupoles, i.e. having 8 magnetic poles combined with 8 electric poles.

According to yet further embodiments, as illustrated in FIGS. 1A to 1D, the first stigmator 112 and the second stigmator 114 can include two orthogonal octupole fields which can be either magnetic or electric or both and can be provided at two positions and in two separate planes.

In FIG. 1A, the charged particle beam device 100 is provided by two stigmators 112 and 114 which are provided at two positions along the optical axis 2 and within two planes such that the fields of the first stigmator 112 and the second stigmator 114 do not overlap.

In the embodiment shown in FIG. 1A, the first stigmator 112 and the second stigmator 114 include electric poles. Each of the electric octupoles 120, of the first stigmator 112 and the second stigmator 114, includes eight electrodes, which are configured to be individually biased. As depicted by the axes 130, the octupole of the second stigmator 114 is not rotated with respect to the octupole of the first stigmator 112. In other words there is an angle of essentially 0°, and in particular an angle of 0°, between the orientation of the first stigmator 112 and second stigmator 114.

According to some embodiments, the first stigmator 112 and the second stigmator are fixed in position, in particular fixed in the plane in which they are positioned, and prevented from rotating.

In the embodiment shown in FIG. 1B, the first stigmator 112 of the double stigmator 110 includes two quadrupoles, for example, quadrupole 116 and quadrupole 118. The second stigmator 114 of the double stigmator 110 includes two quadrupoles, for example, quadrupole 116 and quadrupole 118. Quadrupole 116 includes four poles 160, and quadrupole 118 includes four poles 160. The quadrupole 118 can be rotated with respect to the quadrupole 116, as seen in FIG. 1B. The poles 160 of the quadrupole 116 can be electric poles or magnetic poles. The poles 160 of the quadrupole 118 can be electric poles or magnetic poles. The poles of the quadrupole 116 can be electric and the poles of the quadrupole 118 can be electric. The poles of the quadrupole 116 can be magnetic and the poles of the quadrupole 118 can be magnetic. The poles of the quadrupole 116 can be electric and the poles of the quadrupole 118 can be magnetic. The poles of the quadrupole 116 can be magnetic and the poles of the quadrupole 118 can be electric. The quadrupole 116 can be adjacent to the quadrupole 118. With the first stigmator 112 including the quadrupole 116 and the quadrupole 118, wherein the quadrupole 116 and the quadrupole 118 are in adjacent planes, the first stigmator 112 includes an octupole. The quadrupole 116 and the quadrupole 118 being in adjacent planes can be in adjacent planes along the optical axis 2. The first stigmator 112 and the second stigmator 114 can be spaced apart by a large distance with respect to the dimensions of the charged particle beam column. The first stigmator 112 and the second stigmator 114 can be separated by a distance, along the optical axis 2, of at least 10 mm. For example, the first stigmator 112 and the second stigmator 114 can be separated by a distance of 50 mm. For example a distance between the first stigmator and second stigmator can be at least 3 times, particularly at least 5 times, a distance between the quadrupoles of each of the stigmators.

In the embodiment shown in FIG. 1C, the first stigmator 112 and the second stigmator 114 include magnetic poles. Each of the magnetic octupoles, of the first stigmator 112 and the second stigmator 114, includes eight coils, which are configured to be individually biased. As depicted by the axes 130 in FIG. 1B, the octupole of the second stigmator 114 is not rotated with respect to the octupole of the first stigmator 112 by an angle of essentially 0°, and in particular by an angle of 0°.

FIG. 1D shows a combined electric-magnetic double stigmator 110, wherein the first stigmator 112 includes an octupole including eight coils and the second stigmator 114 includes an octupole including eight electrodes. As depicted by the axes 130, the octupole of the second stigmator 114 is not rotated with respect to the octupole of the first stigmator 112, i.e. there is an angle of essentially 0°, and in particular an angle of 0°. According to yet further embodiments, the first stigmator 112 can include magnetic poles and the second stigmator 114 can include electric poles.

Accordingly, for purely magnetic or purely electric octupoles, the fields can be generated by a single element providing both correction directions or two separated elements—in essentially one plane or in two planes separated along the optical axis-one for each direction.

According to yet further embodiments, which can be combined with other embodiments described herein, the double stigmator 110 can also be used to generate one, more, or all lower order correction fields (defocus, deflection two-fold astigmatism). The double stigmator 110 as described herein can replace some or all of the other compensation components in a column. Particularly for electric octupole elements, lower order correction fields might be additionally generated by the octupole. In this case, other elements in the charged particle beam column can be omitted. For deviating axes of the different orders of correction, an iterative alignment procedure can be beneficial because, for example, a two-fold astigmatism compensation might necessitate a further correction of the deflection and/or numerical aperture.

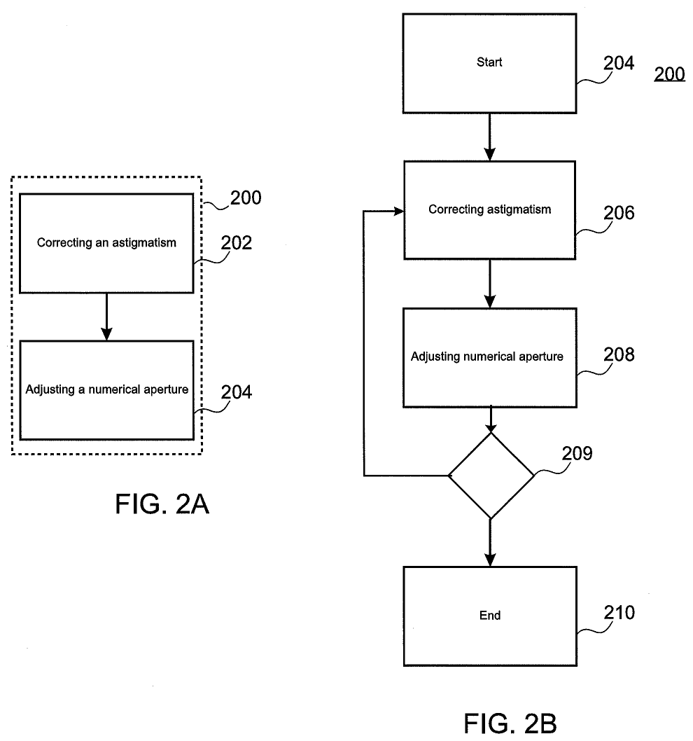

FIG. 2A illustrates a flow chart for illustrating an embodiment of a method 200 for correcting an astigmatism and adjusting a numerical aperture of a charged particle beam; see for example FIG. 1A to 1D, for reference to the charged particle beam device 100 configured to emit a charged particle beam. Particularly, a method for correcting an astigmatism and an asymmetry of a numerical aperture of a charged particle beam with a double stigmator having a first stigmator and a second stigmator can be provided. At operation 202, the method includes correcting the astigmatism of the charged particle beam with a second stigmator 114 of a double stigmator 110. The method 200 further includes at operation 204, adjusting a numerical aperture of the charged particle beam with a first stigmator 112 of the double stigmator, the first stigmator 112 and the second stigmator 114 being spaced apart along an optical axis 2.

According to some embodiments, adjusting the numerical aperture does not affect the corrected astigmatism of the charged particle beam beyond a threshold. For example, the astigmatism of the charged particle beam is corrected and/or adjusted to a sufficient degree, thus, when the numerical aperture is being adjusted, the astigmatism remains as it was set, i.e. below a threshold of 1000 nm, below a threshold of 100 nm, below a threshold of 10 nm, or below any respective threshold. It is beneficial to adjust the numerical aperture virtually independently of the astigmatism because it allows for better and more accurate control of the charged particle beam.

FIG. 2B illustrates a flow chart for illustrating an embodiment of the method 200 for correcting an astigmatism and a numerical aperture of a charged particle beam; see for example FIG. 1A to 1D, for reference to the charged particle beam device 100 configured to emit a charged particle beam. The method 200 can start, e.g. after an initial adjustment of beam parameters or an initial alignment of the beam, according to operation 204. The method 200 can further include operation 206, operation 208, operation 209, and operation 210. Operation 206 includes when conducted the first time, correcting astigmatism of the charged particle with the second stigmator 114. Operation 208, includes adjusting the numerical aperture of the charged particle beam with the first stigmator 112. For example, an asymmetry of the numerical aperture can be corrected. The correction of the numerical aperture can include a correction of asymmetry of the numerical aperture introduced by operation 206 and may optionally also include a correction of a numerical aperture present after an initial beam alignment. Operation 209 includes checking if the astigmatism is below the astigmatism threshold and if the numerical aperture is below a numerical aperture threshold. Operation 209 can include checking based on predetermined values or based on dynamic values which are tailored to the specific process.

When returning back to operation 206, operation 206 includes, correcting astigmatism of the charged particle beam that has been introduced by adjusting the numerical aperture with the second stigmator 114. The term “correcting astigmatism” can be understood as correcting an astigmatism which is introduced in the method/procedure. Operation 208, includes adjusting the numerical aperture of the charged particle beam with the first stigmator 112, e.g. an asymmetry of the numerical aperture introduced by the previous occurrence of operation 206.

An iteration can be provided by repeating adjusting the numerical aperture of the charged particle beam with the first stigmator 112 and correcting astigmatism with the second stigmator 114 until the astigmatism is below the astigmatism threshold and until the numerical aperture is below the numerical aperture threshold. Operation 210 can be understood as the end of the method 200 when the condition for e.g. satisfying the one or more thresholds is met. For example, the astigmatism threshold can be defined as having a distance in the focal plane of 1 μm or below, particularly 100 nm or below. For example, the numerical aperture threshold can be defined as a difference in a numerical aperture (NA) in two orthogonal directions of 20% or below, particularly 5% or below, more particularly of 1% or below. Repeating adjusting the numerical aperture of the charged particle beam can be repeated at least 2, 5 or 20 times.

According to some embodiments, the method 200 further includes determining a value of the astigmatism of the charged particle beam, determining asymmetry characteristics of the numerical aperture of the charged particle beam, calculating correction signals for the first stigmator 112 and the second stigmator 114 based upon the absolute value of the astigmatism and the asymmetry of the numerical aperture, and adjusting the first stigmator 112 and the second stigmator 114 based upon the correction signals.

Adjusting the first stigmator 112 and the second stigmator 114 based on the correction signals is more beneficial the more spaced apart the first stigmator 112 and the second stigmator 114 are, in particular when the correction signals are calculated through diagonalization, for example, matrix diagonalization.

The calculating of the correction signals can comprise diagonally correlating the relationships between the first stigmator and second stigmator with the numerical aperture and astigmatism. For example, the relationships can include the following ratios: change in numerical aperture and excitation of the first stigmator; change in numerical aperture and excitation of the second stigmator; change in astigmatism and excitation of the first stigmator; and change in astigmatism and excitation of the second stigmator. These relationships can be arranged to correlate to one another.

A corresponding matrix for one direction to be corrected can be provided as follows:

$$( \begin{matrix}\frac{δ NA}{δ Stigm 1} & \frac{δ NA}{δ Stigm 2} \\ \frac{δ Ast}{δ Stigm 1} & \frac{δ Ast}{δ Stigm 2}\end{matrix} )$$

These relationships can be diagonalized such that one or more outputs, i.e. one or more eigenvector, can be used to determine the corresponding effects of the first and the second stigmator, on each of the numerical aperture and the astigmatism. The diagonalization can be computed through for example a matrix. The one or more outputs of the diagonalization can be deemed to be sufficient once it reaches one or more threshold values. The one or more threshold values can be predetermined or can be variable. In the case of more than one threshold value, the threshold two or more threshold values do not need to be the same. According to some embodiments, which can be combined with other embodiments described herein, the influence of the first stigmator and the second stigmator can be virtually de-coupled, e.g. by matrix diagonalization. Accordingly, adjustment of the numeral aperture can be provided by the first stigmator and adjusting the astigmatism can be provided by the second stigmator.

According to some embodiments, which can be combined with other embodiments described herein, calculating the correction signals comprises diagonally correlating the relationships between the first stigmator and second stigmator with the numerical aperture and astigmatism. For example, diagonalization of a matrix of correlation can be provided for a set of charged particle beam parameters, including at least one of: a beam energy, a beam current, a beam size (e.g. substantially an average diameter) at the position along the optical axis of the first stigmator, and a beam size (e.g. substantially an average diameter) at the position along the optical axis of the first stigmator.

According to some embodiments, the method 200, wherein the adjusting the numerical aperture can include correcting an asymmetric numerical aperture. In order to correct and/or adjust the asymmetric numerical aperture, the numerical aperture can be beneficially measured.

According to some yet further embodiments, determining the absolute value of the astigmatism can include measuring beam spot information at a plurality of defocus settings and calculating the absolute value of the astigmatism based on the beam spot information. For example, the beam spot information can include any of: images taken directly of the beam spot, refined images of the beam spot, for example, showing the various characteristics of the beam spot, or any combination thereof.

According to some yet further embodiments, determining the asymmetry characteristics of the numerical aperture includes calculating asymmetry characteristics of the numerical aperture based on the beam spot information. For example, the calculations can be performed by an algorithm, such as an image processing algorithm, which can process an image of a beam spot to calculate the various characteristics, such as size, width, length, geometrical points, etc.

According to some embodiments, the first stigmator 112 can be independently adjusting the numerical aperture along two axes. For example, the first stigmator 112 can be adjusting a numerical aperture X-axis and a numerical aperture Y-axis. Adjusting the numerical aperture along two axes is beneficial because for example, if the X-axis needs to be adjusted more, for example significantly more, than the Y-axis, this allows for a more efficient method of adjusting the numerical aperture.

According to some embodiments, the second stigmator 114 can be independently correcting the astigmatism along two axes. For example, the second stigmator 114 can be correcting an astigmatism X-axis and an astigmatism Y-axis (rotated by 45° as compared to the X-axis). Correcting the astigmatism along two axes is beneficial because for example, if the X-axis needs to be corrected more, for example significantly more, than the Y-axis, this allows for a more efficient method of correcting the astigmatism.

According to some embodiments, each of the first stigmator 112 and the second stigmator 114 can include of at least two quadrupoles. For example, at least one of the at least two quadrupoles is acting on the X-axis and at least one of the at least two quadrupoles is acting on the Y-axis. Some embodiments can further include independently controlling each of the at least two quadrupoles of each of the first stigmator 112 and the second stigmator 114.

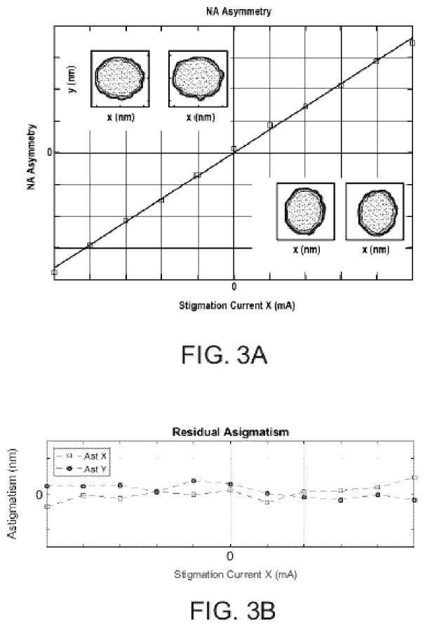

FIGS. 3A to 3B illustrate graphs depicting a proof of concept of correcting an astigmatism and a numerical aperture.

FIG. 3A is an example of the results of combining the first stigmator 112 and the second stigmator 114 to form the double stigmator 110; see for example FIG. 1A to 1D, for reference to the charged particle beam device 100, described herein. In order to evaluate the capability of combining the two stigmators to correct astigmatism and adjust numerical aperture, the quadrupole fields of a first stigmator (see, e.g. 112 in FIG. 1) introduce asymmetric NA and, thereby, creates astigmatism. This astigmatism is corrected by the second stigmator 114. The residual astigmatism is close to 0 (FIG. 3B) while the NA asymmetry remains the same.

In the example illustrated in FIG. 3A, the beam cross sections are shown at −x μm and +x μm (“x” being an exemplary offset) of the focus position when a negative stigmation current is applied and when a positive stigmation current is applied. It can be seen that a negative stigmation current has a larger influence on the X-axis of the asymmetric numerical aperture. The illustrations of the beam cross sections depict that there is minimal to zero astigmatism when either the negative stigmation current is applied or when the positive stigmation current is applied. Particularly, the illustrations of the beam cross sections depict that there is minimal to zero effect on the orientation, in other words, that the orientation of the beam cross section is the same, or essentially the same, at the two focus positions. Thus, the astigmatism remains zero due to the action (or combination) of the two stigmators.

FIG. 3B shows an example of the residual astigmatism of the first stigmator 112 and the second stigmator for the proof of concept of FIG. 3A of the combined first stigmator 112 and the second stigmator 114 to form the double stigmator 110; see for example FIG. 1A to 1D, for reference to the charged particle beam device 100, described herein. The remaining astigmatism can be considered to be negligible. This can explain the shapes of the beam cross sections illustrated in FIG. 3A.

In principle, the charged particle beam device and the method of correcting an astigmatism and a numerical aperture of a charged particle beam are beneficial in allowing for correction of an asymmetrical numerical aperture. The asymmetrical numerical aperture can be corrected in combination with correcting the astigmatism, and in particular two-fold astigmatism.

In light of the above, a plurality of embodiments are disclosed, some of which are listed below:

Embodiment 1. A method of correcting an astigmatism and adjusting a numerical aperture of a charged particle beam with a double stigmator having a first stigmator and a second stigmator, comprising: correcting the astigmatism of the charged particle beam with the second stigmator of a double stigmator; and adjusting the numerical aperture of the charged particle beam with the first stigmator of the double stigmator, the first stigmator and the second stigmator being spaced apart along an optical axis.

Embodiment 2. The method of embodiment 1, further comprising: correcting astigmatism of the charged particle beam that has been introduced by adjusting the numerical aperture with the second stigmator; and repeating adjusting the numerical aperture of the charged particle beam with the first stigmator and correcting astigmatism with the second stigmator until the astigmatism is below an astigmatism threshold and until the numerical aperture is below a numerical aperture threshold.

Embodiment 3. The method of embodiment 1, further comprising: determining an absolute value of the astigmatism of the charged particle beam; determining an asymmetry characteristics of the numerical aperture of the charged particle beam; calculating correction signals for the first stigmator and the second stigmator based upon the absolute value of the astigmatism and the asymmetry characteristics of the numerical aperture; and adjusting the first stigmator and the second stigmator based upon the correction signals.

Embodiment 4. The method of embodiment 3, wherein calculating the correction signals comprises diagonally correlating the relationships between the first stigmator and second stigmator with the numerical aperture and astigmatism.

Embodiment 5. The method of any of embodiments 1 to 4, wherein the adjusting the numerical aperture comprises: correcting an asymmetric numerical aperture.

Embodiment 6. The method of any of embodiments 4 to 5, wherein determining the absolute value of the astigmatism comprises: measuring beam spot information at a plurality of defocus settings; and calculating the absolute value of the astigmatism based on the beam spot information.

Embodiment 7. The method of embodiment 6, wherein determining the asymmetry characteristics of the numerical aperture comprises: calculating the asymmetry characteristics of the numerical aperture based on the beam spot information.

Embodiment 8. The method of any of embodiment 1 to 7, wherein the first stigmator is independently adjusting the numerical aperture along two directions.

Embodiment 9. The method of any of embodiments 1 to 8, wherein the second stigmator is independently correcting the astigmatism along the two directions.

Embodiment 10. The method according to any of embodiments 1 to 9, wherein each of the first stigmator and the second stigmator is comprising of at least two quadrupoles.

Embodiment 11. The method according to embodiment 10, further comprising: independently controlling each of the at least two quadrupoles of each of the first stigmator and the second stigmator.

Embodiment 12. A charged particle beam device (100), comprising: a charged particle beam column; a charged particle beam source (10) provided within the charged particle beam column and configured to emit a charged particle beam along an optical axis (2); an objective lens (14) configured to focus the charged particle beam on a specimen (20); a stage (22) configured to support the specimen; and a double stigmator (110) configured to correct an astigmatism and a numerical aperture, the double stigmator comprises: a first stigmator; and a second stigmator, the first stigmator and the second stigmator being separated along the optical axis. The charged particle beam device further comprises a controller (150) configured to perform the method according to any of embodiments 1 to 11.

Embodiment 13. The charged particle beam device according to embodiment 12, wherein the double stigmator comprises any of 16 or more magnetic poles, 16 or more electric poles, or a combination of 16 or more poles including magnetic poles and electric poles.

Embodiment 14. The charged particle beam device according to any of embodiments 12 to 13, wherein a combination of the first stigmator and the second stigmator are configured to independently control four degrees of freedom.

Embodiment 15. The charged particle beam device according to embodiment 14, wherein the four degrees of freedom are numerical aperture in an X-axis and numerical aperture in a Y-axis, and astigmatism in an X-axis and astigmatism in a Y-axis.

Embodiment 16. The charged particle beam device according to any of embodiments 12 to 15, wherein the first stigmator and the second stigmator are separated by at least 5 mm along the optical axis, preferably by at least 25 mm along the optical axis.

Embodiment 17. The charged particle beam device according to any of embodiments 12 to 16, wherein each stigmator comprises an octupole.

Embodiment 18. The charged particle beam device according to any of embodiments 12 to 17, wherein the first stigmator and the second stigmator have the same rotation orientation.

Embodiment 19. The charged particle beam device according to any of embodiments 12 to 18, wherein the double stigmator is configured to adjust an asymmetric numerical aperture.

Embodiment 20. The charged particle beam device according to any of embodiments 12 to 19, wherein each stigmator is fixed in its position.

While the foregoing is directed to embodiments of the invention, other and further embodiments of the invention may be devised without departing from the basic scope thereof, and the scope thereof is determined by the claims that follow.

1. A method of correcting an astigmatism and adjusting a numerical aperture of a charged particle beam with a double stigmator having a first stigmator and a second stigmator, comprising:
correcting the astigmatism of the charged particle beam with the second stigmator of a double stigmator; and
adjusting the numerical aperture of the charged particle beam with the first stigmator of the double stigmator, the first stigmator and the second stigmator being spaced apart along an optical axis.

2. The method of claim 1, further comprising:
correcting astigmatism of the charged particle beam that has been introduced by adjusting the numerical aperture with the second stigmator; and
repeating adjusting the numerical aperture of the charged particle beam with the first stigmator and correcting astigmatism with the second stigmator until the astigmatism is below an astigmatism threshold and until the numerical aperture is below a numerical aperture threshold.

3. The method of claim 1, further comprising:
determining an absolute value of the astigmatism of the charged particle beam;
determining an asymmetry characteristics of the numerical aperture of the charged particle beam;
calculating correction signals for the first stigmator and the second stigmator based upon the absolute value of the astigmatism and the asymmetry characteristics of the numerical aperture; and
adjusting the first stigmator and the second stigmator based upon the correction signals.

4. The method of claim 3, wherein calculating the correction signals comprises diagonally correlating the relationships between the first stigmator and second stigmator with the numerical aperture and astigmatism.

5. The method of claim 1, wherein the adjusting the numerical aperture comprises:
correcting an asymmetric numerical aperture.

6. The method of claim 4, wherein determining the absolute value of the astigmatism comprises:
measuring beam spot information at a plurality of defocus settings; and
calculating the absolute value of the astigmatism based on the beam spot information.

7. The method of claim 6, wherein determining the asymmetry characteristics of the numerical aperture comprises:
calculating the asymmetry characteristics of the numerical aperture based on the beam spot information.

8. The method of claim 1, wherein the first stigmator is independently adjusting the numerical aperture along two directions.

9. The method of claim 1, wherein the second stigmator is independently correcting the astigmatism along the two directions.

10. The method of claim 1, wherein each of the first stigmator and the second stigmator is comprising of at least two quadrupoles.

11. The method claim 10, further comprising:
independently controlling each of the at least two quadrupoles of each of the first stigmator and the second stigmator.

12. A charged particle beam device, comprising:
a charged particle beam column;
a charged particle beam source provided within the charged particle beam column and configured to emit a charged particle beam along an optical axis;
an objective lens configured to focus the charged particle beam on a specimen;
a stage configured to support the specimen; and
a double stigmator configured to correct an astigmatism and a numerical aperture, the double stigmator comprises:
a first stigmator;
a second stigmator, the first stigmator and the second stigmator being separated along the optical axis; and
a controller configured to perform a method of correcting an astigmatism and adjusting a numerical aperture of a charged particle beam with a double stigmator having a first stigmator and a second stigmator, the method comprising:
correcting the astigmatism of the charged particle beam with the second stigmator of a double stigmator; and
adjusting the numerical aperture of the charged particle beam with the first stigmator of the double stigmator, the first stigmator and the second stigmator being spaced apart along an optical axis.

13. The charged particle beam device according to claim 12, wherein the double stigmator comprises any of 16 or more magnetic poles, 16 or more electric poles, or a combination of 16 or more poles including magnetic poles and electric poles.

14. The charged particle beam device according to any of claim 12, wherein a combination of the first stigmator and the second stigmator are configured to independently control four degrees of freedom.

15. The charged particle beam device according to claim 14, wherein the four degrees of freedom are numerical aperture in an X-axis and numerical aperture in a Y-axis, and astigmatism in an X-axis and astigmatism in a Y-axis.

16. The charged particle beam device according to claim 12, wherein the first stigmator and the second stigmator are separated by at least 5 mm along the optical axis, preferably by at least 25 mm along the optical axis.

17. The charged particle beam device according to claim 12, wherein each stigmator comprises an octupole.

18. The charged particle beam device according to claim 12, wherein the first stigmator and the second stigmator have the same rotation orientation.

19. The charged particle beam device according to claim 12, wherein the double stigmator is configured to adjust an asymmetric numerical aperture.

20. The charged particle beam device according to claim 12, wherein each stigmator is fixed in its position.
